(19) United States
(12) Patent Application Publication
(10) Pub. No.: US 2026/0288017 A1
(43) Pub. Date: Sep. 24, 2026

(54) METROLOGY METHOD AND ASSOCIATED METROLOGY AND LITHOGRAPHIC APPARATUSES

(71) Applicant: ASML Netherlands B.V., Veldhoven (NL)

(72) Inventor: Patricius Aloysius Jacobus TINNEMANS, Hapert (NL)

(73) Assignee: ASML Netherlands B.V., Veldhoven (NL)

(21) Appl. No.: 19/469,957

(22) PCT Filed: Mar. 8, 2024
(86) PCT No.: PCT/EP2024/056279

§ 371 Date: Sep. 26, 2025

(30) Foreign Application Priority Data
Apr. 12, 2023 (EP) 23167496.1

(51) Int. Cl. G03F 7/00

(52) U.S. Cl. CPC G03F 7/706837; G03F 7/70633; G03F 7/706841; G03F 7/706851

(57) ABSTRACT

Disclosed is a method of metrology relating to measurement of a structure on a substrate, said structure being subject to process variation. The method comprises obtaining first measurement data relating to a phase of measurement radiation having been scattered from one or more marks, and relating to a plurality of measurement conditions; obtaining second measurement data relating to an intensity of said measurement radiation and relating to said plurality of measurement conditions; obtaining a weighting for said first measurement data and second measurement data, said weighting comprising a modulus component relating to a modulus of complex weights and an argument component relating to an argument of the complex weights; and determining a first parameter value for a first parameter from said first measurement data and said second measurement data, as weighted by said weighting.

### CROSS-REFERENCE TO RELATED APPLICATIONS

This application claims priority of EP Application Serial No. 23167496.1 which was filed on 12 Apr. 2023 and which is incorporated herein in its entirety by reference

### FIELD OF THE INVENTION

The present invention relates to methods and apparatuses usable, for example, in the manufacture of devices by lithographic techniques, and to methods of manufacturing devices using lithographic techniques. The invention relates more particularly to metrology sensors and lithography apparatuses having such a metrology sensor.

### BACKGROUND ART

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. These target portions are commonly referred to as “fields”.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down (by the same apparatus or a different lithographic apparatus) in previous layers. For this purpose, the substrate is provided with one or more sets of alignment marks. Each mark is a structure whose position can be measured at a later time using a position sensor, typically an optical position sensor. The lithographic apparatus includes one or more alignment sensors by which positions of marks on a substrate can be measured accurately. Different types of marks and different types of alignment sensors are known from different manufacturers and different products of the same manufacturer.

In other applications, metrology sensors are used for measuring exposed structures on a substrate (either in resist and/or after etch). A fast and non-invasive form of specialized inspection tool is a scatterometer in which a beam of radiation is directed onto a target on the surface of the substrate and properties of the scattered or reflected beam are measured. Examples of known scatterometers include angle-resolved scatterometers of the type described in US2006033921A1 and US2010201963A1. In addition to measurement of feature shapes by reconstruction, diffraction based overlay can be measured using such apparatus, as described in published patent application US2006066855A1. Diffraction-based overlay metrology using dark-field imaging of the diffraction orders enables overlay measurements on smaller targets. Examples of dark field imaging metrology can be found in international patent applications WO 2009/078708 and WO 2009/106279 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

In some metrology applications, such as in some scatterometers or alignment sensors, imperfections in metrology targets can result in a wavelength/polarization dependent variation in a measured value from that target. As such, correction and/or mitigation for this variation is sometimes effected by performing the same measurement using multiple different wavelengths and/or polarizations (or more generally, multiple different measurement conditions). It would be desirable to improve one or more aspects of measuring using multiple measurement conditions.

### SUMMARY OF THE INVENTION

The invention in a first aspect provides a method of metrology relating to measurement of a structure on a substrate, said structure being subject to process variation, the method comprising: obtaining first measurement data relating to a phase of measurement radiation having been scattered from one or more marks, and relating to a plurality of measurement conditions; obtaining second measurement data relating to an intensity of said measurement radiation and relating to said plurality of measurement conditions; obtaining a weighting for said first measurement data and second measurement data, said weighting comprising a modulus component relating to a modulus of complex weights and an argument component relating to an argument of the complex weights; and determining a first parameter value for a first parameter from said first measurement data and said second measurement data, as weighted by said weighting.

Also disclosed is a computer program, alignment sensor and a lithographic apparatus being operable to perform the method of the first aspect.

The above and other aspects of the invention will be understood from a consideration of the examples described below.

### BRIEF DESCRIPTION OF THE DRAWINGS

Embodiments of the invention will now be described, by way of example only, with reference to the accompanying drawings, in which:

FIG. 1 depicts a lithographic apparatus;

FIG. 2 illustrates schematically measurement and exposure processes in the apparatus of FIG. 1;

FIG. 3 is a schematic illustration of an alignment sensor adaptable according to an embodiment of the invention; and

FIG. 4 is a schematic illustration of a measurement on an alignment mark.

### DETAILED DESCRIPTION OF EMBODIMENTS

Before describing embodiments of the invention in detail, it is instructive to present an example environment in which embodiments of the present invention may be implemented.

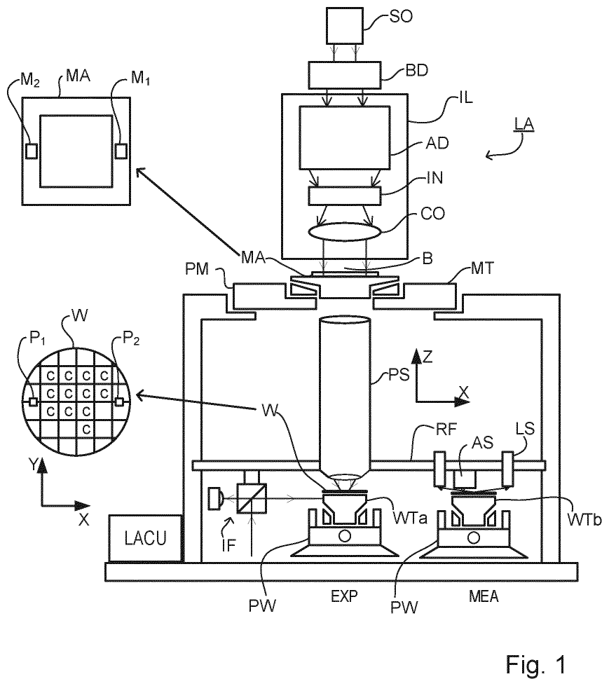

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA 5 with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables WTa, WTb and two stations—an exposure station EXP and a measurement station MEA—between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

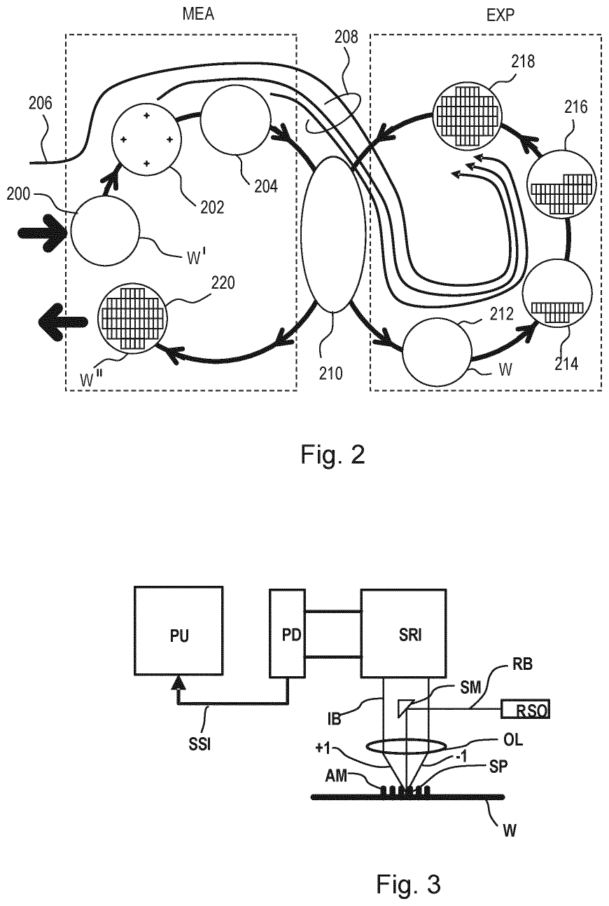

FIG. 2 illustrates the steps to expose target portions (e.g. dies) on a substrate W in the dual stage apparatus of FIG. 1. On the left hand side within a dotted box are steps performed at a measurement station MEA, while the right hand side shows steps performed at the exposure station EXP. From time to time, one of the substrate tables WTa, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. These processing steps progressively introduce distortions in the substrate that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

At 202, alignment measurements using the substrate marks P1 etc. and image sensors (not shown) are used to measure and record alignment of the substrate relative to substrate table WTa/WTb. In addition, several alignment marks across the substrate W′ will be measured using alignment sensor AS. These measurements are used in one embodiment to establish a “wafer grid”, which maps very accurately the distribution of marks across the substrate, including any distortion relative to a nominal rectangular grid.

At step 204, a map of wafer height (Z) against X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. To these recipe data are added the measurements of wafer position, wafer grid and height map that were made at 202, 204, so that a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the ‘ideal’ grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports WTa and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly WTa) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example rather than measuring alignment in a single pass, often there will be separate phases of coarse and fine measurement, using the same or different marks. The coarse and/or fine alignment measurement steps can be performed before or after the height measurement, or interleaved.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down in previous layers (by the same apparatus or a different lithographic apparatus). For this purpose, the substrate is provided with one or more sets of marks. Each mark is a structure whose position can be measured at a later time using a position sensor, typically an optical position sensor. The position sensor may be referred to as “alignment sensor” and marks may be referred to as “alignment marks”.

A lithographic apparatus may include one or more (e.g. a plurality of) alignment sensors by which positions of alignment marks provided on a substrate can be measured accurately. Alignment (or position) sensors may use optical phenomena such as diffraction and interference to obtain position information from alignment marks formed on the substrate. An example of an alignment sensor used in current lithographic apparatus is based on a self-referencing interferometer as described in U.S. Pat. No. 6,961,116. Various enhancements and modifications of the position sensor have been developed, for example as disclosed in US2015261097A1. The contents of all of these publications are incorporated herein by reference.

A mark, or alignment mark, may comprise a series of bars formed on or in a layer provided on the substrate or formed (directly) in the substrate. The bars may be regularly spaced and act as grating lines so that the mark can be regarded as a diffraction grating with a well-known spatial period (pitch). Depending on the orientation of these grating lines, a mark may be designed to allow measurement of a position along the X axis, or along the Y axis (which is oriented substantially perpendicular to the X axis). A mark comprising bars that are arranged at +45 degrees and/or −45 degrees with respect to both the X- and Y-axes allows for a combined X- and Y-measurement using techniques as described in US2009/195768A, which is incorporated by reference.

The alignment sensor scans each mark optically with a spot of radiation to obtain a periodically varying signal, such as a sine wave. The phase of this signal is analyzed, to determine the position of the mark and, hence, of the substrate relative to the alignment sensor, which, in turn, is fixated relative to a reference frame of a lithographic apparatus. So-called coarse and fine marks may be provided, related to different (coarse and fine) mark dimensions, so that the alignment sensor can distinguish between different cycles of the periodic signal, as well as the exact position (phase) within a cycle. Marks of different pitches may also be used for this purpose.

Measuring the position of the marks may also provide information on a deformation of the substrate on which the marks are provided, for example in the form of a wafer grid. Deformation of the substrate may occur by, for example, electrostatic clamping of the substrate to the substrate table and/or heating of the substrate when the substrate is exposed to radiation.

FIG. 3 is a schematic block diagram of an embodiment of a known alignment sensor AS. Radiation source RSO provides a beam RB of radiation of one or more wavelengths, which is diverted by diverting optics onto a mark, such as mark AM located on substrate W, as an illumination spot SP. In this example the diverting optics comprises a spot mirror SM and an objective lens OL. The illumination spot SP, by which the mark AM is illuminated, may be slightly smaller in diameter than the width of the mark itself.

Radiation diffracted by the mark AM is collimated (in this example via the objective lens OL) into an information-carrying beam IB. The term “diffracted” is intended to include complementary higher diffracted orders; e.g.: +1 and −1 diffracted orders (labelled +1, −1) and optionally zero-order diffraction from the mark (which may be referred to as reflection). A self-referencing interferometer SRI, e.g. of the type disclosed in U.S. Pat. No. 6,961,116 mentioned above, interferes the beam IB with itself after which the beam is received by a photodetector PD. Additional optics (not shown) may be included to provide separate beams in case more than one wavelength is created by the radiation source RSO. The photodetector may be a single element, or it may comprise a number of pixels, if desired. The photodetector may comprise a sensor array.

The diverting optics, which in this example comprises the spot mirror SM, may also serve to block zero order radiation reflected from the mark, so that the information-carrying beam IB comprises only higher order diffracted radiation from the mark AM (this is not essential to the measurement, but improves signal to noise ratios).

SRI Intensity signals SSI are supplied to a processing unit PU. By a combination of optical processing in the self-referencing interferometer SRI and computational processing in the unit PU, values for X- and Y-position on the substrate relative to a reference frame are output.

A single measurement of the type illustrated only fixes the position of the mark within a certain range corresponding to one pitch of the mark. Coarser measurement techniques are used in conjunction with this to identify which period of a sine wave is the one containing the marked position. The same process at coarser and/or finer levels are repeated at different wavelengths for increased accuracy and/or for robust detection of the mark irrespective of the materials from which the mark is made, and materials on and/or below which the mark is provided. Improvements in performing and processing such multiple wavelength measurements are disclosed below.

It is known that alignment marks (and other metrology targets) may be deformed by process variations (PV) substrate-to-substrate leading to on-product overlay errors. The term “mark” will be used herein to refer to any structure which may be measured in the methods disclosed herein; such structures may comprise alignment marks formed for the purpose of alignment, other metrology marks or targets formed for the purpose of metrology, and/or product structure which may be measured to obtain a metrology and/or position value.

In the context of wafer alignment, concepts such as OCW (Optimal Color Weighing) and the related OCIW (Optimal Color and Intensity Weighing) are in use or have been proposed to correct the mark position for such process variation (e.g., mark asymmetry, i.e., asymmetry in the alignment mark which results in a position error or offset). These concepts are described in more detail in the publications US2019/0094721, WO 2017032534A2, US2020/0272061A1 and US2020/0081356A1, all of which are incorporated herein by reference). Another concept comprises MCLR (Multi-Color Lowest Residuals) described in more detail in PCT publication WO2022184405A1 which is incorporated herein by reference.

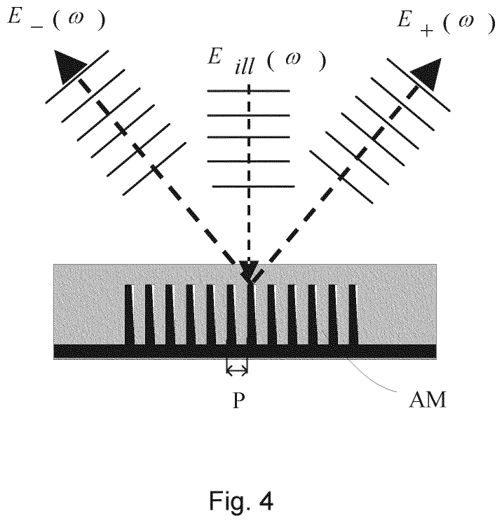

The measured (e.g., alignment and/or phase) data Δ_{MEAS}(ω) will comprise (e.g., the sum of) a component due to process variation (e.g., mark asymmetry or mark deformation) Δ_{MD}(ω) and the desired wafer deformation component Δ_{WD} (i.e., desired position value or first parameter value). The process variation component shows a color-to-color variation (i.e., color dependence, i.e., angular frequency dependence), while the desired wafer deformation component Δ_{WD} has no such dependency (at least for positive ω). A definition for angular frequency ω is given below, in the description accompanying FIG. 4.

To address this, many alignment sensors are provided with the functionality to measure each alignment mark using multiple different measurement conditions (e.g., combinations of wavelength and polarization; note that “color” will be used throughout the description as shorthand for measurement condition, i.e., wavelength and polarization combination). In more basic techniques, an average of these per-color measurements and/or one or more better performing measurements are used to determine the aligned position. In OCW, a per-color weighting for the measurement data (e.g., alignment data) may be determined, the weighting comprising (e.g., trained) positive and negative weights which minimize the impact of process variation on a parameter of interest such as overlay (or, for example, any other placement parameter such as edge placement error). The weighting should sum to unity to preserve the alignment signal.

OCIW is an improvement on OCW, where the metrology tool/alignment sensor has additional intensity channel functionality which can measure individually intensities of two complementary diffraction orders from each mark (e.g., the +1 and −1 orders, although pairs of higher orders are theoretically possible). In OCIW, an additional intensity weighting is determined for an intensity imbalance signal (e.g., based on an imbalance, such as a difference or ratio, of these +1 and −1 diffraction orders). In OCIW, the color weighting and intensity weighting may be trained together, again to minimize the impact of process variation on a parameter of interest such as overlay.

A main physics mechanism of OCW and OCIW is that the weighting creates (near) orthogonality to the process variation observed in the training data.

Another weighting technique may comprise a weighting based on “wafer quality” WQ or other mark reflectance metric (e.g., (normalized) reflectance of the mark). The term wafer quality or WQ will be used herein to refer to any such measure of mark reflectance (or signal amplitude) from the target. In WQ-weighting, only positive weights are used and these weights do not require training. However, these weights are determined per alignment mark, e.g., from the (normalized) reflectance of that alignment mark. The main physics mechanism of WQ-weighting is that weighting via target reflectance improves convergence of target asymmetry dispersion sum rule(s). Other metrics which may be used comprise a signal strength metric (e.g., intensity or amplitude metric) and/or measurement noise metric.

An issue with present OCW and OCIW weighting is that it is not adaptive, which means that the algorithm itself cannot adapt real time to (new) process variations that were not present in the training data. Another issue is that negative weights give rise to an increase of the weight vector length (2-norm of the weights), which results in measurement noise to be magnified, compared to best color or average color recipes. An issue with the WQ-weighting algorithm is that it does not point to the geometric point of interest of the customer, but instead points to an optical density center of mass of the deformed grating. And this optical density center of mass of the deformed grating still depends on the mark deformation.

As such, a method is proposed comprising a complex weighted OCIW, where the imposed weights are complex, insofar as they comprise a modulus component and an (e.g., trained) argument component. This allows for a first-principles physics backed weighting scheme for first measurement data (e.g., phase data or alignment data) and second measurement data (e.g., intensity imbalance data), in which the modulus of the complex weights comprises the reflectance metric, WQ, signal strength metric and/or measurement noise metric, and the argument of the complex weights is the trained component.

An advantage of complex weights over positive and negative weights, is that it allows for a reduction of the number of parameters (e.g., weights) to be trained compared to present OC(I)W techniques, which may reduce the necessary amount of training data.

The fact that the modulus of the complex weights equals the WQ per mark means that the imposed weighting is adaptive, which is expected to be beneficial when process variations occur which were not in the training data (i.e., it improves extrapolation behavior and/or generalization performance).

The fact that the argument of the complex weights is trained, allows training of the algorithm to determine a particular point or position of interest for an application (i.e., the position that is of interest from an overlay point of view), as opposed to the (mark deformation dependent) optical density center of mass of the deformed grating. The same trained weights may be used to impose a weighting on both the colors and the intensities (intensity asymmetry indicator).

FIG. 4 shows an example alignment mark AM comprising grating deformation and a pitch P, being measured using alignment illumination described by an (frequency ω dependent) electric field Eᵢₗₗ(ω), and the captured diffraction orders are respectively described by electric fields E₋(ω), E₊(ω), where:

$${E}_{+} ( ω ) = \sqrt{{I}_{+} ( ω )} \cdot {e}^{( - i {φ}_{+} ( ω ) )}$$

$${E}_{-} ( ω ) = \sqrt{{I}_{-} ( ω )} \cdot {e}^{( - i {φ}_{-} ( ω ) )}$$

where I₊, I₋ are the measured intensities of each diffraction order of a complementary pair (e.g., +1, −1 pair), φ₊, φ₋ are the phases of these orders, ω=2πc/λ, λ is the measurement wavelength and c is the speed of light.

The alignment data Δ_{MEAS}(ω) is related to the measured phase difference, e.g., as measured by phase channels of an alignment sensor:

$${Δ}_{MEAS} ( ω ) = \frac{P}{4 π n} \cdot ( {φ}_{+} ( ω ) - {φ}_{-} ( ω ) )$$

Additionally, an intensity asymmetry indicator α(ω), may be measured, for example, in the intensity channels of an alignment sensor:

$$α ( ω ) = \frac{P}{4 π n} \cdot \frac{1}{2} \cdot log ( \frac{{I}_{+} ( ω )}{{I}_{-} ( ω )} )$$

where P>0 denotes the (apparent) grating period and n is a positive integer indicating the diffraction order. It can be appreciated that the intensity asymmetry indicator α(ω) has the same unit as the measured position Δ_{MEAS}(ω).

The dependence on angular frequency ω results from the Fourier transform

$$G ( ω ) = {\int }_{- ∞}^{+ ∞} g ( t ) {e}^{i ω t} dt ,$$

rather than from illuminating with a certain wavelength; consequently negative angular frequencies ω<0 require consideration. It can be shown that reversing propagation direction has no effect on the observed intensities, so I₊(−ω)=I₊(ω) and I₋(−ω)=I₋(ω). This implies that φ₊(−ω)=−φ₊(ω) and φ₋(−ω)=−φ₋(ω). This in turn implies real-valued electric fields E₋(t), E₊(t), and some dependence of wafer deformation Δ_{WD} on angular frequency ω, i.e., Δ_{WD}(−ω)=−Δ_{WD}(ω).

It has been proposed to apply (e.g., Kramers-Kronig) dispersion relations to analyze the measurement data. In Hilbert transform notation

$${H}_{T} ( G ( ω ) ) = \frac{1}{π} \cdot {\int }_{- ∞}^{+ ∞} \frac{G ( {ω}^{′} )}{ω - {ω}^{′}} d {ω}^{′} ,$$

such dispersion relations may comprise asymmetry relations:

$$\frac{α ( ω )}{ω} = {H}_{T} ( \frac{{Δ}_{MD} ( ω )}{ω} ) ,$$

and its inverse

$$\frac{{Δ}_{MD} ( ω )}{ω} = - {H}_{T} ( \frac{α ( ω )}{ω} )$$

Or in an alternative variant, based on product formula

$${H}_{T} ( ω \cdot G ( ω ) ) = ω \cdot {H}_{T} ( G ( ω ) ) - \frac{1}{π} \cdot {\int }_{- ∞}^{+ ∞} G ( {ω}^{′} ) d {ω}^{′} : α ( ω ) = {H}_{T} ( {Δ}_{MD} ( ω ) ) ,$$

and its inverse

$${Δ}_{MD} ( ω ) = - {H}_{T} ( α ( ω ) )$$

and therefore:

$${Δ}_{WD} = {Δ}_{MEAS} ( ω ) - {Δ}_{MD} ( ω ) = {Δ}_{MEAS} ( ω ) + {H}_{T} ( α ( ω ) )$$

A dispersion physics based OCIW example can be constructed. If F(ω) and G(ω) are square integrable, then

$$F ( ω ) \cdot G ( ω ) \cdot d ω = {\int }_{- ∞}^{+ ∞} {H}_{T} ( F ( ω ) ) \cdot {H}_{T} ( G ( ω ) ) \cdot d ω .$$

Therefore if F(ω)=W(ω) (weights) and G(ω)=Δ_{MD}(ω), then, based on α(ω)=H_{T}(Δ_{MD}(ω))=H_{T}(Δ_{MEAS}(ω)−Δ_{WD}):

$${\int }_{- ∞}^{+ ∞} W ( ω ) \cdot ( {Δ}_{MEAS} ( ω ) - {Δ}_{WD} ) \cdot d ω = {\int }_{- ∞}^{+ ∞} {H}_{T} ( W ( ω ) ) \cdot α ( ω ) \cdot d ω$$

Assuming that

$${\int }_{- ∞}^{+ ∞} W ( ω ) \cdot d ω \neq 0$$

and solving for Δ_{WD}:

$${Δ}_{WD} = \frac{{\int }_{- ∞}^{+ ∞} W ( ω ) \cdot {Δ}_{MEAS} ( ω ) \cdot d ω - {\int }_{- ∞}^{+ ∞} {H}_{T} ( W ( ω ) ) \cdot α ( ω ) \cdot d ω}{{\int }_{- ∞}^{+ ∞} W ( ω ) \cdot d ω}$$

However, while such dispersion physics based approaches have sound theoretical basis, the requirement to perform a Hilbert transform makes such approaches difficult to implement in practice. This is because of the limited wavelength range and sampling density used in the alignment measurement (e.g., typically 12 wavelengths spanning a single octave), while Kramers-Kronig type dispersion analysis requires a set of wavelengths 0≤λ≤∞ as input (or at least an approximation over multiple octaves). The existing OCIW algorithm addresses this issue by (for example) training the result of the Hilbert transform. However, an improved approach will be described herein, which removes the need to perform any Hilbert transforms and therefore obviates the issue of limited wavelength range of the measurement radiation.

The proposed approach uses the concept of complex weighting. Defining complex weights as W(ω)=w·e^{iωt} and noting H_{T}(w·e^{iωt})=−i·w·e^{iωt} if t≥0, then:

$${\int }_{- ∞}^{+ ∞} w \cdot {e}^{i ω t} \cdot ( {Δ}_{MEAS} ( ω ) - {Δ}_{WD} ) \cdot d ω = - i \cdot {\int }_{- ∞}^{+ ∞} w \cdot {e}^{i ω t} \cdot α ( ω ) \cdot d ω \\ {\int }_{- ∞}^{+ ∞} w \cdot {e}^{i ω t} \cdot ( {Δ}_{M E A S} ( ω ) - {Δ}_{WD} + i \cdot α ( ω ) ) \cdot d ω = 0 if t \geq 0$$

Redefining the complex weighting as

$$W ( ω ) = {\int }_{0}^{+ ∞} w ( t ) \cdot {e}^{i ω t} \cdot dt$$

and noting that the inverse Fourier transform of W(ω) is a causal function

$${H}_{T} ( W ( ω ) ) = {H}_{T} ( {\int }_{0}^{+ ∞} w ( t ) \cdot {e}^{i ω t} \cdot dt ) = - i \cdot {\int }_{0}^{+ ∞} w ( t ) \cdot {e}^{i ω t} \cdot α ( ω ) \cdot dt = - i \cdot W ( ω ) ,$$

as the Hilbert transform is a linear transform, yields:

$${\int }_{- ∞}^{+ ∞} W ( ω ) \cdot ( {Δ}_{MEAS} ( ω ) - {Δ}_{WD} ) \cdot d ω = - i \cdot {\int }_{- ∞}^{+ ∞} W ( ω ) \cdot α ( ω ) \cdot d ω \\ {\int }_{- ∞}^{+ ∞} W ( ω ) \cdot ( {Δ}_{MEAS} ( ω ) - {Δ}_{WD} + i \cdot α ( ω ) ) \cdot d ω = 0 if W ( ω ) = {\int }_{0}^{+ ∞} w ( t ) \cdot {e}^{i ω t} \cdot dt$$

It is proposed herein that the complex weights, in an embodiment, are defined as W(ω)=r(ω)·e^{iθ(ω)}, where θ(ω)≥0. It can be appreciated that the criterion θ(ω)≥0 enforces the inverse Fourier transform of W(ω)=r(ω)·e^{iθ(ω)} to be causal. This criterion may be thought of as a generalization of real valued (i.e. positive, zero and/or negative) weighting.

Because wafer quality is a measured quantity, it has finite energy and a causal inverse Fourier transform. As such, in an embodiment, the modulus of the weighting r(ω) may describe the (per mark or per measurement location) wafer quality or reflectance metric, while only the argument θ(ω) is trained. The training may be performed, as before, using first data (e.g., alignment data) and corresponding reference data (e.g., overlay data), for example as measured from training wafers. The concepts are not limited to alignment data color weighting, and as such, the first data may be as appropriate to the application; for example for weighing overlay data (e.g., as measured by a scatterometer), the first data may be overlay data with the reference data being reference overlay data (e.g., as measured using an scanning electron microscope/e-beam tool).

Solving

$${\int }_{- ∞}^{+ ∞} r ( ω ) \cdot {e}^{i θ ( ω )} \cdot ( {Δ}_{MEAS} ( ω ) - {Δ}_{WD} + i \cdot α ( ω ) ) \cdot d ω = 0$$

for first parameter value or desired (wafer deformation component) position value Δ_{WD}, where θ(ω)≥0, yields:

$${Δ}_{WD} = \frac{{\int }_{- ∞}^{+ ∞} r ( ω ) \cdot {e}^{i θ ( ω )} \cdot ( {Δ}_{MEAS} ( ω ) + i \cdot α ( ω ) ) \cdot d ω}{{\int }_{- ∞}^{+ ∞} r ( ω ) \cdot {e}^{i θ ( ω )} \cdot d ω}$$

The complex weighting can be interpreted physically as follows. Consider: Δ̅_{MD}(w)+i·\tilde{α}(ω)=r(ω)·e^{iθ(ω)}·(Δ_{MD}(ω)+i·α(ω))=r(ω)·e^{iθ(ω)}·(Δ_{MEAS}(ω)−Δ_{WD}+i·α(ω)). The inverse Fourier transforms of Δ_{MD}(ω)+i·α(ω) and r(ω)·e^{iθ(ω)} are causal if θ(ω)≥0. Therefore, the inverse Fourier transform of \tilde{Δ}_{MD}(ω)+i·\tilde{α}(ω) is also causal, as the convolution of two causal functions is causal. As such, complex weighting can be interpreted as average color of \tilde{Δ}_{MD}(ω)+i·\tilde{α}(ω). The product with complex weights r(ω)·e^{iθ(ω)} can be thought of as a conformal mapping function.

Alternative, and more convenient recitations of the formula for the first parameter value or desired (wafer deformation component) position value Δ_{WD} may comprise:

$${Δ}_{WD} = \frac{{\int }_{0}^{+ ∞} Re ( W ( ω ) ) \cdot {Δ}_{MEAS} ( ω ) \cdot d ω - {\int }_{0}^{+ ∞} Im ( W ( ω ) ) \cdot α ( ω ) \cdot d ω}{{\int }_{0}^{+ ∞} Re ( W ( ω ) ) \cdot d ω}$$

and therefore:

$${Δ}_{WD} = \frac{\begin{matrix}{\int }_{0}^{+ ∞} r ( ω ) \cdot cos ( θ ( ω ) ) \cdot {Δ}_{MEAS} ( ω ) \cdot d ω - \\ {\int }_{0}^{+ ∞} r ( ω ) \cdot sin ( θ ( ω ) ) \cdot α ( ω ) \cdot d ω\end{matrix}}{{\int }_{0}^{+ ∞} r ( ω ) \cdot cos ( θ ( ω ) ) \cdot d ω}$$

where, as before, the argument or polar angle θ(ω) is trained and r(ω) may be the wafer quality or reflectance metric WQ(ω). As such, said first parameter value may be determined from weighted first measurement data (or a weighted derivative over frequency (or wavelength) of the first measurement data) and a weighted derivative over frequency (or wavelength) of the second measurement data.

As such, a corrected position Δ_{WD} (e.g., per mark) may be obtained from first measurement data or phase measurement data Δ_{MEAS}(ω) (e.g., with values per mark and per measurement condition), second measurement data or intensity imbalance measurement data α(ω) (e.g., again with values per mark and per measurement condition), wafer quality/reflectance metric data WQ(ω) and the trained polar angle θ(ω) using any of the equations for Δ_{WD} described above.

The training may be essentially the same as with present OCW and OCIW techniques, e.g., it may comprise finding the weighting which maximizes performance of said reference data. This may comprise finding the weighting which minimizes (e.g., de-corrected) overlay (reference data) when applied to corresponding first training data or phase training data Δ_{MEAS}(ω) and second training data or intensity training data α(ω). The training data may be obtained from training wafers and/or actual production wafers.

In an alternative, the training may determine the weighting such that the weighting maximizes performance of the first parameter value (e.g., corrected position or overlay) i.e., the performance of the first parameter is the objective. This may cover both a training and/or an evaluation (i.e., after the training) context. Ultimately, the training objective is only a proxy for the evaluation (i.e., after the training) performance.

In a further embodiment, it may be appreciated that as the Hilbert transform is angular frequency shift invariant, then the proposed algorithms described above may also be angular frequency shift invariant. As such, the trained polar angle θ(ω) may be chosen to be angular frequency shift invariant; i.e., such that θ(ω)=θ. In an embodiment, this polar angle may be ±45°, as it can be demonstrated that this angle is favorable in terms of measurement noise, signal energy and geometric arguments. This yields:

$${Δ}_{WD} = \frac{{\int }_{0}^{+ ∞} r ( ω ) \cdot ( {Δ}_{MEAS} ( ω ) ∓ α ( ω ) ) \cdot d ω}{{\int }_{0}^{+ ∞} r ( ω ) \cdot d ω} \approx \frac{{\sum }_{λ} r ( λ ) \cdot ( {Δ}_{MEAS} ( λ ) ∓ α ( λ ) )}{{\sum }_{λ} r ( λ )}$$

In this embodiment, therefore, the magnitude of the polar angle is fixed and requires no training; only the sign is trained (i.e., determining whether the sum or the difference of the phase measurement data and intensity imbalance measurement data is used to determine the wafer deformation Δ_{WD}). As such, a per-mark choice of sign ∓ may be trained (or determined otherwise, e.g., using dispersion sum rules) and used in combination with the wafer quality (e.g., for r(ω) or r(λ)) to determine the weighting. As such, the argument component of the weighting in this embodiment may comprise an imposed +1 or −1 binary weighting on said second measurement data or intensity imbalance measurement data α(ω).

As such, the proposed methods address the inaccuracy of Hilbert transforms when measurements are performed with only limited wavelengths, by introducing complex weighting. A First principles dispersion physics derived algorithm archetype is described which
makes OCIW adaptive, includes intensity channels in WQ-weighting and
includes negative weights in WQ-weighting.

While specific embodiments of the invention have been described above, it will be appreciated that the invention may be practiced otherwise than as described.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

Aspects of the invention are set out in the clauses below.
1. A method of metrology relating to measurement of a structure on a substrate, said structure being subject to process variation, the method comprising: obtaining first measurement data relating to a phase of measurement radiation having been scattered from one or more marks, and relating to a plurality of measurement conditions; obtaining second measurement data relating to an intensity of said measurement radiation and relating to said plurality of measurement conditions; obtaining a weighting for said first measurement data and second measurement data, said weighting comprising a modulus component relating to a modulus of complex weights and an argument component relating to an argument of the complex weights; and determining a first parameter value for a first parameter from said first measurement data and said second measurement data, as weighted by said weighting.
2. A method as claimed in clause 1, wherein said first measurement data comprises alignment data and said first parameter value is a position value.
3. A method as claimed in clause 1, wherein said first measurement data comprises overlay data and said first parameter value is an overlay value.
4. A method as claimed in any preceding clause, wherein said second measurement data comprises intensity imbalance measurement data.
5. A method as claimed in any preceding clause, wherein said modulus component comprises one or more of: a reflectance metric, wafer quality metric, signal strength metric and/or measurement noise metric of each said mark.
6. A method as claimed in any preceding clause, wherein said first parameter value is determined from weighted first measurement data and weighted second measurement data, said weighted second measurement data comprising a weighted derivative over frequency or wavelength of the second measurement data.
7. A method as claimed in clause 6, wherein said weighted first measurement data comprises a weighted derivative over frequency or wavelength of the first measurement data.
8. A method as claimed in clause 6 or 7, wherein said first parameter value is determined from a difference of said weighted first measurement data and weighted second measurement data.
9. A method as claimed in any of clauses 6 to 8, wherein said weighted first measurement data is weighted by a real part of said complex weights and said weighted second measurement data is weighted by an imaginary part of said complex weights.
10. A method as claimed in any preceding clause, wherein a real part of said complex weights comprises a product of said modulus component and a first function of the argument component, and an imaginary part of said complex weights comprises a product of said modulus component and a second function of the argument component; and wherein the first function and second function comprise periodic functions have a respective polar angle difference of π/2.
11. A method as claimed in any of clauses 1 to 6, wherein said argument component is substantially angular frequency invariant.
12. A method as claimed clause 11, wherein said argument describes a polar angle of +45° or −45°.
13. A method as claimed in clause 11 or 12, wherein said argument component comprises a +1 or −1 binary weighting on said second measurement data.
14. A method as claimed in any of clauses 11 to 13, wherein said determining a first parameter value comprises determining the first parameter from a derivative or sum over frequency or wavelength of a product of the modulus component and a sum of the first measurement data and weighted second measurement data.
15. A method as claimed in any preceding clause, wherein said determining a parameter value comprises normalizing the first parameter value.
16. A method as claimed in any preceding clause, wherein said weighting imposes, for each mark, a respective weight to said first measurement data per measurement condition.
17. A method as claimed in any preceding clause, wherein said argument component has been previously trained in a training phase.
18. A method as claimed in any of clauses 1 to 16, wherein the modulus of said argument component has been previously trained in a training phase, and the sign of said argument component is determined after measuring said second measurement data.
19. A method as claimed in any preceding clause, comprising performing said training phase, said training phase comprising: obtaining first training data of the same data type as said first measurement data; obtaining second training data of the same data type as said second measurement data; obtaining reference data corresponding to said first training data and said second training data; and determining said argument component such that said weighting maximizes performance of either: said first parameter value; or said reference data when applied to said first training data and second training data.
20. A method as claimed in clause 19, wherein said reference data comprises overlay data.
21. A method as claimed in clause 20, wherein said overlay data is processed to remove any corrections imposed in accordance with the first measurement data.
22. A method as claimed in any preceding clause, comprising performing a subsequent exposure on said substrate in accordance with said first parameter value.
23. A computer program comprising program instructions operable to perform the method of any of clauses 1 to 21, when run on a suitable apparatus.
24. A non-transient computer program carrier comprising the computer program of clause 23.
25. A processing system comprising a processor and a storage device comprising the computer program of clause 23.
26. An alignment sensor operable to perform the method of any of clauses 1 to 21.
27. A lithographic apparatus comprising: a patterning device support for supporting a patterning device; a substrate support for supporting a substrate; and the alignment sensor of clause 26.

The breadth and scope of the present invention should not be limited by any of the above-described exemplary embodiments, but should be defined only in accordance with the following claims and their equivalents.

1-15. (canceled)

16. A method of metrology relating to measurement of a structure on a substrate, the structure being subject to process variation, the method comprising:
obtaining first measurement data relating to a phase of measurement radiation having been scattered from one or more marks on the substrate and relating to a plurality of measurement conditions;
obtaining second measurement data relating to an intensity of the measurement radiation and relating to the plurality of measurement conditions;
obtaining a weighting for the first measurement data and second measurement data, the weighting comprising a modulus component relating to a modulus of complex weights and an argument component relating to an argument of the complex weights; and
determining a first parameter value for a first parameter from the first measurement data and the second measurement data, as weighted by the weighting.

17. The method of claim 16, wherein the first measurement data comprises alignment data and the first parameter value is a position value.

18. The method of claim 16, wherein the first measurement data comprises overlay data and the first parameter value is an overlay value.

19. The method of claim 16, wherein the second measurement data comprises intensity imbalance measurement data.

20. The method of claim 16, wherein the modulus component comprises one or more of: a reflectance metric, wafer quality metric, signal strength metric and/or measurement noise metric of each of the mark.

21. The method of claim 16, wherein the first parameter value is determined from weighted first measurement data and weighted second measurement data, the weighted second measurement data comprising a weighted derivative over frequency or wavelength of the second measurement data.

22. The method of claim 21, wherein the weighted first measurement data comprises a weighted derivative over frequency or wavelength of the first measurement data.

23. The method of claim 21, wherein the first parameter value is determined from a difference of the weighted first measurement data and weighted second measurement data.

24. The method of claim 21, wherein the weighted first measurement data is weighted by a real part of the complex weights and the weighted second measurement data is weighted by an imaginary part of the complex weights.

25. The method of claim 16, wherein a real part of the complex weights comprises a product of the modulus component and a first function of the argument component, and an imaginary part of the complex weights comprises a product of the modulus component and a second function of the argument component; and wherein the first function and second function comprise periodic functions have a respective polar angle difference of π/2.

26. The method of claim 16, wherein the argument component is substantially angular frequency invariant.

27. The method of claim 26, wherein the argument describes a polar angle of +45° or −45°.

28. The method of claim 26, wherein the argument component comprises a +1 or −1 binary weighting on the second measurement data.

29. The method of claim 26, wherein the determining a first parameter value comprises determining the first parameter from a derivative or sum over frequency or wavelength of a product of the modulus component and a sum of the first measurement data and weighted second measurement data.

30. The method of claim 16, wherein the determining a parameter value comprises normalizing the first parameter value.

31. The method of claim 16, wherein the weighting imposes, for each mark, a respective weight to the first measurement data per measurement condition.

32. The method of claim 16, comprising performing the training phase, the training phase comprising:
obtaining first training data of the same data type as the first measurement data;
obtaining second training data of the same data type as the second measurement data;
obtaining reference data corresponding to the first training data and the second training data; and
determining the argument component such that the weighting maximizes performance of either: the first parameter value; or the reference data when applied to the first training data and second training data.

33. The method of claim 32, wherein the reference data comprises overlay data.

34. A computer program comprising program instructions operable to perform the method of claim 16, when run on a suitable apparatus.

35. An alignment sensor operable to perform the method of claim 16.
